(19) United States
(12) Patent Application Publication
(10) Pub. No.: US 2010/0261345 A1
(43) Pub. Date: Oct. 14, 2010

(54) METHOD OF MANUFACTURING A SEMICONDUCTOR DEVICE

(75) Inventor: Jong-Jin NA, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/750,959

(22) Filed: Mar. 31, 2010

(30) Foreign Application Priority Data
Apr. 10, 2009 (KR) 2009-31065

(51) Int. Cl. H01L 21/768

(52) U.S. Cl. 438/622; 257/E21.585

(57) ABSTRACT

In a semiconductor device and method of manufacturing thereof, a first insulation interlayer is formed on a substrate including a lower conductive pattern. The first insulation interlayer has a first opening through which the lower conductive pattern is exposed. An interconnection is formed in the first opening such that the interconnection is contact with the lower conductive pattern and protruded from the first insulation interlayer. A second insulation interlayer is formed on the first insulation interlayer in such a manner that the second insulation interlayer has a second opening through the interconnection is exposed and the second opening is centrally aligned with the interconnection. An upper conductive pattern is formed in the second opening such that the upper conductive pattern is contacted with the interconnection. Accordingly, a mis-alignment between the upper conductive pattern and the interconnection is prevented.

### CROSS-REFERENCE TO RELATED APPLICATIONS

This application claims priority under 35 U.S.C. §119 from Korean Patent Application No. 2009-31065, filed on Apr. 10, 2009 in the Korean Intellectual Property Office (KIPO), the contents of which are herein incorporated by reference in their entirety.

### BACKGROUND

1. Field of the General Inventive Concept

Example embodiments relate to a semiconductor device and a method of manufacturing the same, and more particularly, to a semiconductor device having a wiring interconnections and methods of manufacturing the same.

2. Description of the Related Art

Recently, unit devices of an integrated circuit, such as conductive structures of a memory device, are vertically and sequentially stacked on a substrate in a medium of an insulation interlayer and lower and upper unit devices are electrically connected to each other through a conductive interconnection such as a contact plug or a via plug in accordance with device requirements of high integration degree and high performance. Thus, a line interval and a line width of a conductive pattern in the semiconductor device have been rapidly reduced and the size of the interconnection has been also reduced.

The requirements of a small width and low electrical resistance in the conductive pattern of a semiconductor device necessarily causes a relatively large height of the conductive pattern, and thus the insulation interlayer tends to be formed to a large thickness for electrically separating the lower and upper conductive patterns. For that reason, the interconnection also tends to be formed into a large height so as to penetrate the insulation interlayer.

Due to the reduced width and the increased height of the interconnection, the contact area between the interconnection and the conductive pattern is also reduced, which requires a much more accurate aligning process between the interconnection and the conductive pattern in manufacturing a semiconductor device. That is, a slight mis-alignment between the interconnection and the conductive pattern would mostly lead to contact failure or insufficient contact between the interconnection and the conductive pattern.

Further, the slight mis-alignment between the interconnection and the conductive pattern would also lead to a frequent physical contact between neighboring interconnections, which is widely known as a bridge defect, since the line interval between the neighboring interconnections are largely decreased.

For the above reasons, there is a need for an improved manufacturing process in which the mis-alignment between the interconnection and the conductive pattern in a semiconductor device is sufficiently reduced. Particularly, a central alignment between an interconnection and an upper conductive structure has been strongly needed in a wiring process for a semiconductor device in view of the current manufacturing environments in which a slight and minute mis-alignment between the interconnection and the upper conductive structure results in the bridge defect.

### SUMMARY

Example embodiments include a semiconductor device in which an interconnection and a conductive pattern are formed under central alignment conditions.

Other example embodiments provide a method of manufacturing the above semiconductor device.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing a semiconductor device including a substrate having at least a lower conductive pattern, a first insulation interlayer on the substrate such that the lower conductive pattern is covered with the first insulation interlayer and is electrically insulated by the first insulation interlayer, the first insulation interlayer having a first opening through which the lower conductive pattern is exposed, an interconnection disposed in the first opening of the first insulation interlayer such that the interconnection makes contact with the lower conductive pattern, the interconnection being protruded from the first insulation interlayer in such a configuration that an upper surface of the interconnection is higher than an upper surface of the first insulation interlayer, a second insulation interlayer on the first insulation interlayer, the second insulation interlayer having a second opening that is centrally aligned with the interconnection and exposes the interconnection, and at least an upper conductive pattern in the second opening, the upper conductive pattern making contact with the interconnection.

In some example embodiments, the second insulation interlayer may include a lower insulation layer on the first insulation interlayer and an upper insulation layer on the lower insulation layer, an etching rate of the upper insulation layer being smaller than that of the lower insulation layer. For example, the first insulation interlayer may include silicon oxide, the lower insulation layer includes silicon nitride and the upper insulation layer includes silicon oxide.

The semiconductor device may further include a second interconnection centrally aligned over the upper conductive pattern in a third opening, and a second upper conductive pattern disposed in a second centrally aligned opening making contact with the second interconnection.

The foregoing and/or other aspects and utilities of the present general inventive concept may also be achieved by providing a method of manufacturing the semiconductor device. A substrate having at least a lower conductive pattern may be prepared. A first insulation interlayer may be formed on the substrate in such a manner that the lower conductive pattern is covered with the first insulation interlayer and is electrically insulated by the first insulation interlayer and the first insulation interlayer has a first opening through which the lower conductive pattern is exposed. Then, an interconnection may be formed in the first opening in such a manner that the interconnection is contacted with the lower conductive pattern and may be protruded from the first insulation interlayer, so that an upper surface of the interconnection may be higher than an upper surface of the first insulation interlayer. A second insulation interlayer may be formed on the first insulation interlayer in such a manner that the second insulation interlayer has a second opening through which the interconnection may be exposed and the second opening is centrally aligned with the interconnection. At least an upper conductive pattern may be formed in the second opening such that the upper conductive pattern is contacted with the interconnection.

In some example embodiments, the second insulation interlayer may be formed by a lower insulation layer being formed on the first insulation interlayer from which the interconnection is protruded to a sufficient thickness to cover the protruded interconnection, so that the lower insulation layer includes a first protrusion portion to correspond to the protruded portion of the interconnection. An upper insulation layer may be formed on the lower insulation layer along a surface profile of the lower insulation layer in such a manner that the upper insulation layer has an etching rate smaller than that of the lower insulation layer, so that the upper insulation layer includes a second protrusion portion to correspond to the first protrusion portion of the lower insulation layer. The upper insulation layer may be partially removed from the lower insulation layer until an upper surface of the first protrusion of the lower insulation layer is exposed, so that an upper surface of the upper insulation layer is coplanar with the upper surface of the first protrusion of the lower insulation layer. The first protrusion portion of the lower insulation layer may be partially removed from the first insulation interlayer, to thereby forming the second opening through which the protruded portion of the interconnection is exposed.

In some example embodiments, the upper insulation layer may be removed by one of a CMP process and an etch-back process against the upper insulation layer.

In some example embedment, the etching rate of the lower insulation layer may be from about 3 times to about 10 times the etching rate of the upper insulation layer. The first protrusion portion of the lower insulation layer may be performed by one of a wet etching process using an aqueous HF solution as an etchant and a plasma dry etching process. The interconnection and the upper conductive pattern may include one of polysilicon, a low electrical resistive metal and combinations thereof. Examples of the low electrical resistive metal may include tungsten (W), titanium (Ti), tantalum (Ta), etc. These may be used alone and in combinations thereof.

The foregoing and/or other aspects and utilities of the present general inventive concept may be achieved by providing forming a substrate having a lower conductive pattern formed thereon, forming a first insulation interlayer over the substrate and the conductive pattern, masking the first insulation interlayer to form an opening of a predetermined size, forming the opening and determining a central axis of the opening equidistant from the sides of the first insulation layer that define the opening, forming a conductive interconnect in the first opening, forming a plurality of insulation layers above the conductive interconnect, and self-aligning a second opening over the first opening such that a center of the second opening is centrally aligned with the central axis of the first opening.

A lower insulation layer may be formed to protrude above the conductive interconnect, the lower insulation layer having a first etch selectivity, an upper insulation layer may be formed above the lower insulation layer, the upper insulation layer having a second etch selectivity higher than the first etch selectivity, a top portion of the upper insulation layer may be removed to expose an upper surface of the lower insulation layer, and the lower insulation layer may be etched to a width edge barrier of the upper insulation film that acts as an etch stop to define the sides of the second opening.

A surface of the lower insulation layer may be anisotropically etched to downwardly remove the lower insulation layer to expose a top portion of the conductive interconnect within the second opening.

The first insulation interlayer may act as an etch stop layer for the anisotropic etching process to thereby prevent the second opening from horizontally enlarging along the first insulation interlayer.

The lower and upper insulation layers may include protrusion portions that have the same central axis as the conductive interconnect formed within the first opening.

A conductive pattern in the second opening may be centrally aligned with the first opening.

The second opening may be defined by dimensions of the plurality of insulating layers.

According to some example embodiments of the present general inventive concept, the second opening through which the interconnection may be exposed may be centrally self-aligned with the interconnection not by a photolithography process using a mask pattern but by etching rate difference between the first insulation interlayer and the second insulation interlayer, and thus the upper conductive pattern may be centrally self-aligned with the interconnection automatically. Thus, various process defects caused by mis-alignment between the interconnection and the upper conductive pattern may be sufficiently prevented.

### BRIEF DESCRIPTION OF THE DRAWINGS

The above and/or other features and utilities of the present general inventive concept will become apparent and more readily appreciated from the following description of the exemplary embodiments, taken in conjunction with the accompanying drawings, in which:

FIG. 1 is a cross-sectional view illustrating semiconductor device including a central-aligned interconnection in accordance with an example embodiment of the present general inventive concept; and

FIGS. 2A to 2H are cross sectional views illustrating processing operations to manufacture the semiconductor device illustrated in FIG. 1 in accordance with an example embodiment of the present general inventive concept.

FIG. 3 is a cross-sectional view illustrating a multi-level semiconductor device including a central-aligned interconnection scheme in accordance with an example embodiment of the present general inventive concept.

### DETAILED DESCRIPTION OF THE EMBODIMENTS

Various example embodiments will be described more fully hereinafter with reference to the accompanying drawings, in which some example embodiments are illustrated. The present general inventive concept may, however, be embodied in many different forms and should not be construed as limited to the example embodiments set forth herein. Rather, these example embodiments are provided so that this disclosure will be thorough and complete, and will fully convey the scope of the present general inventive concept to those skilled in the art. In the drawings, the sizes and relative sizes of layers and regions may be exaggerated for clarity.

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present general inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present general inventive concept. As used herein, the singular forms “a,” “an” and “the” are intended to include the plural forms as well, unless the context clearly indicates otherwise. It will be further understood that the terms “comprises,” “includes” and/or “comprising” or “including,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present general inventive concept.

Unless otherwise defined, all terms (including technical and scientific terms) used herein have the same meaning as commonly understood by one of ordinary skill in the art to which the present general inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

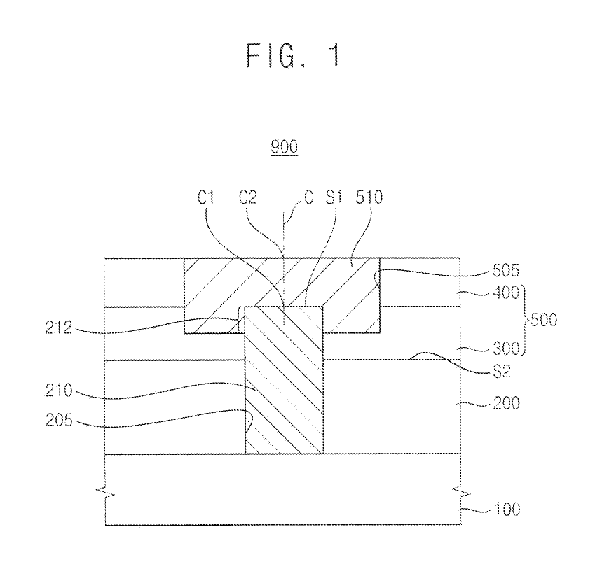

FIG. 1 is a cross-sectional view illustrating semiconductor device including a central-aligned interconnection in accordance with an example embodiment of the present general inventive concept.

Referring to FIG. 1, a semiconductor device 900 in accordance with an example embodiment of the present general inventive concept may include a substrate 100 on which at least one lower conductive pattern (not illustrated) may be arranged, a first insulation interlayer 200 having a first opening 205 with a center axis “C” through which the lower conductive pattern on the substrate 100 is partially exposed, an interconnection 210 filled into the first opening 205 in such a configuration that the lower conductive pattern (not illustrated) may contact with the interconnection 210 and a top surface S1 of the interconnection 210 may be higher than a top surface S2 of the first insulation interlayer 200. The interconnection 210 is center-aligned with the center axis C of the first opening 205 in such a way as to ensure that all other conductive layers disposed atop the interconnection 210 are aligned along the center axis C. A second insulation interlayer 500 may be arranged on the first insulation interlayer 200 to have a second opening 505 of which the central line C may extend and be aligned with the interconnection 210 through a center of the interconnection 210. The semiconductor device 900 may also include a centrally-aligned upper conductive pattern 510 to fill up the second opening 505 and make contact with the interconnection 210.

In an example embodiment, the substrate 100 may include a semiconductor substrate including single crystalline silicon, SiGe, GaAs, SOI and other substrates known in the art and a plurality of the lower conductive patterns for an integrated circuit device may be arranged on the semiconductor substrate. A field isolation pattern (not illustrated) may be arranged on the substrate 100 and thus an active region may be defined on the substrate 100 to include any number of active devices and passive components. A gate electrode and source/drain electrodes for various memory devices may be positioned on the active region of the substrate 100. The memory device may include a volatile memory device such as random access memory (DRAM) device that may have relatively higher input/output (I/O) speeds and lose data stored therein when power is shut off. In other embodiments, a non-volatile memory device such as read-only memory (ROM) devices with floating-gate electrodes that may have relatively lower I/O speeds and maintain data stored therein when power is shut off may be manufactured. Thus, the lower conductive pattern may include different gate structures, a wiring structure and a storage electrode of a capacitor that may be arranged in a cell area of a DRAM or ROM device or may include a conductive contact pad and a wiring structure for a plate electrode of a capacitor that may be arranged in a peripheral area of the DRAM or ROM device. In addition, the lower conductive structure may also include a string selection line, a word line and a ground selection line in a flash memory device.

As illustrated in FIG. 1, the lower conductive pattern (not illustrated) on the substrate 100 may be covered with the first insulation interlayer 200 having the first opening 205 and thus may be electrically insulated from the upper conductive structure. The lower conductive pattern may be partially exposed through the first opening 205. For example, the first insulation interlayer 200 may include an oxide layer having good gap-fill characteristics. The oxide layer for the first insulation interlayer 200 may include a boron phosphorous silicate glass (BPSG) layer, a phosphorous silicate glass (PSG) layer, a silicon on glass (SOG) layer and a tetraethyl ortho silicate (TEOS) layer.

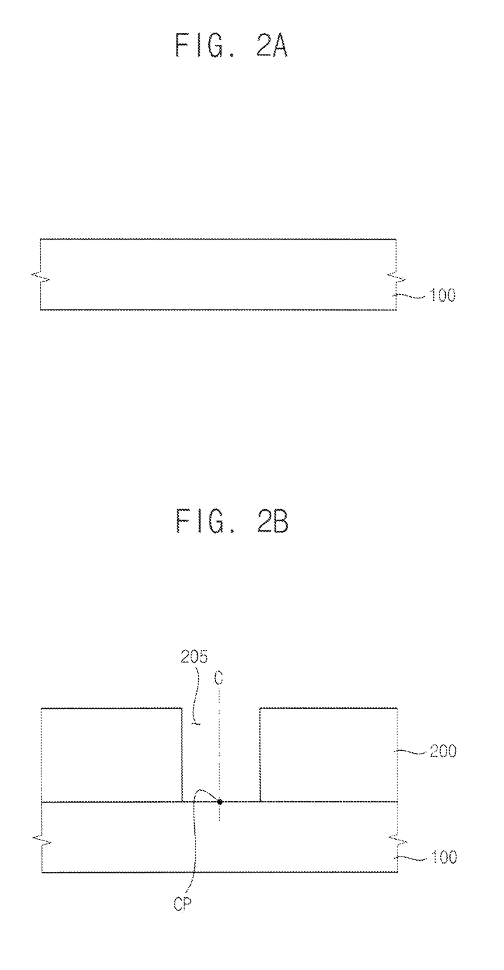

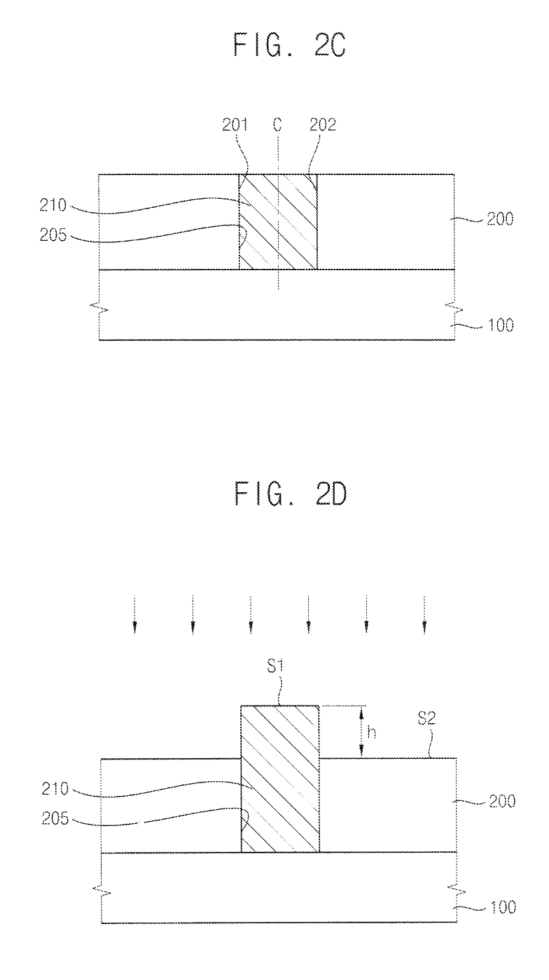

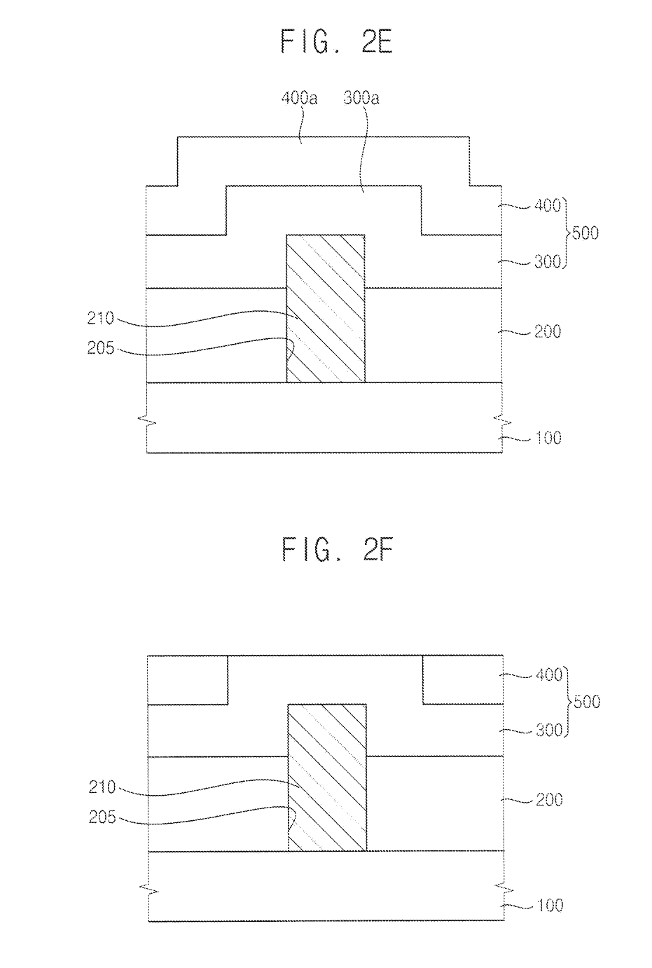

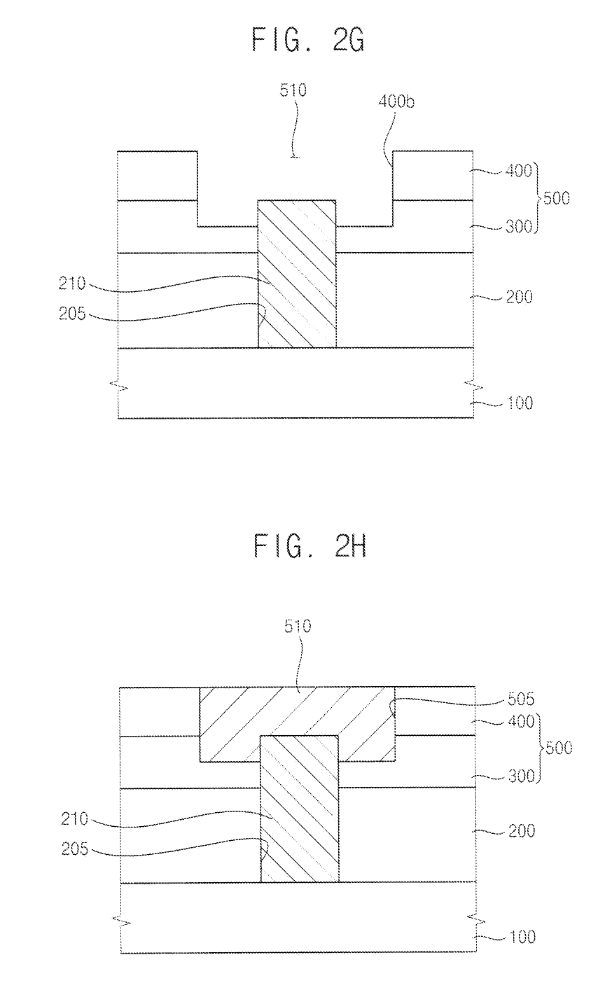

First conductive materials may be filled into the first opening 205 and the interconnection 210 may be centrally positioned in the first opening 205 and may make contact with the lower conductive pattern in the first opening 205. For example, the interconnection 210 may include a contact plug or a via-plug to electrically connect a lower and an upper wiring in a multilayered wiring structure. The conductive material may include low electrically-resistive metal materials. Example of the low electrically-resistive metal material may include tungsten (W), copper (Cu), aluminum (Al), titanium (Ti), tantalum (Ta), etc. These may be used alone or in combinations thereof. A barrier layer (illustrated in FIGS. 2D and 2E) may be further interposed between the first insulation interlayer 200 and the interconnection 210. Thus, the materials of the interconnection may be prevented from diffusing into the insulation interlayer 200 by the barrier layer. In the present example embodiment, a top surface S1 of the interconnection 210 may be higher than an upper surface S2 of the insulation interlayer 200 and thus the interconnection 210 may be protruded from the insulation interlayer 200.

The second insulation interlayer 500 may be positioned on the first insulation interlayer 200 and have the second opening 505 into which an upper portion 212 of the interconnection 210, which may be protruded from the first insulation interlayer 200, may be exposed. The second opening 505 may be centrally aligned with the interconnection 210, the first opening 205 and the central axis C.

In an example embodiment, the second insulation interlayer 500 may include a lower insulation layer 300 on the first insulation interlayer 200 and an upper insulation layer 400 on the lower insulation layer 300. The upper insulation layer 400 may have etch-resistivity superior to that of the lower insulation layer 300. For example, the lower insulation layer 300 may include silicon nitride and the upper insulation layer 400 may include silicon oxide having lower etching rate than the silicon oxide. The second opening 505 may extend through the upper insulation layer 400 into the lower insulation layer 300.

The second opening 505 may be formed by a self-aligned etching process using a difference of the etching rate between the lower and the upper insulation layers 300 and 400, and thus the center C2 of the second opening 505 and the center C1 of the interconnection 210 may be aligned in the same central line C of the first opening 205. The second opening 505 may be formed not by a direct etching process against the upper insulation interlayer 500 using an etching mask pattern but by a relative etching process using the etching rate difference between the lower and the upper insulation layer 300 and 400, and thus the second opening 505 may be self-aligned with the interconnection 210. Accordingly, the interconnection 210 may be exposed through the second opening 505 in such a configuration that the center C1 of the interconnection 210 may be aligned with the center C2 of the second opening 505 along the same central line C which may allow smaller contact areas to be more accurately aligned to connect electrical components such as interconnections and conductive patterns through thicker insulation interlayers.

The upper conductive pattern 510 including second conductive materials may be positioned in the self-aligned second opening 505. For example, the upper conductive pattern 510 may include an upper wiring structure in a multi-layered wiring structure and the second conductive material may include a low electrically resistive metal such as tungsten (W), aluminum (Al) and copper (Cu). Since the second opening 505 may be centrally aligned with the interconnection 210, the upper conductive pattern 510 filling up the second opening 505 may also be centrally aligned with the interconnection 210.

According to the above example embodiment of the present general inventive concept, the upper electrode pattern and the interconnection may be centrally aligned with each other along the same central line, to thereby minimize the bridge defect between neighboring interconnections and the contact failure between the upper conductive pattern and the interconnection even though the pattern size of the interconnection and the conductive pattern may be reduced.

Hereinafter, a method of manufacturing the semiconductor device illustrated in FIG. 1 will be described in detail with reference to FIGS. 2A to 2H.

FIGS. 2A to 2H are cross sectional views illustrating processing operations to manufacture the semiconductor device illustrated in FIG. 1 in accordance with an example embodiment of the present general inventive concept.

Referring to FIGS. 1 and 2A, the substrate 100 including at least one lower conductive pattern may be prepared to manufacture the semiconductor device 900.

In an example embodiment, the substrate 100 may include a semiconductor substrate such as a single crystalline silicon or other types substrates as are known in the art and the lower conductive pattern may include a unit conductive structure for a DRAM device, ROM device, or a flash memory device.

Referring to FIGS. 1 and 2B, the first insulation interlayer 200 having the first opening 205 may be formed on the substrate 100 in such a manner that a lower conductive pattern (not illustrated) may be partially exposed through the first opening 205.

In an example embodiment, the first insulation interlayer 200 may fill up spaces between the lower conductive patterns and may cover the lower conductive patterns on the substrate 100. Thus, the lower conductive patterns may be electrically insulated from each other by the first insulation interlayer 200. For example, the first insulation interlayer 200 may include a DRAM insulation interlayer having a contact pad for a DRAM device and a flash insulation interlayer having a common source line for a flash memory device.

In an example embodiment, the first insulation interlayer 200 may include silicon oxide having good gap-fill characteristics. For example, the first insulation interlayer 200 may include boron phosphorous silicate glass (BPSG), phosphorous silicate glass (PSG), fluorinated silicate glass (FSG), undoped silicate glass (USG) and tetraethyl ortho-silicate (TEOS) deposited by plasma enhanced chemical vapor deposition (PECVD) process (PETEOS). The above insulation materials may be deposited onto the substrate 100 along a surface profile of the substrate including the lower conductive structure by a CVD process, particularly a PECVD process, to a sufficient thickness to fill up the spaces between the lower conductive structures to thereby form a first conductive layer on the substrate having a sufficient thickness to cover the lower conductive structures. Then, the first conductive layer may be planarized by a planarization process such as a chemical mechanical polishing (CMP) process, and thus a top surface of the first insulation interlayer 200 may be formed to be flat.

In the present example embodiment, the first insulation interlayer 200 may include PETEOS. That is, the first insulation interlayer 200 may be formed on the substrate 100 by a PECVD process using tetra-ethoxy silane (Si(OC2H5)4) gas and oxygen (O2) or ozone (O3) gas as a source gas. Otherwise, the first insulation interlayer 200 may include an oxide deposited by high density plasma CVD process or undoped silicate glass when the second insulation interlayer 500 may include PETEOS.

A mask pattern (not illustrated) may be formed on the first insulation interlayer 200 in such a manner that the first insulation interlayer 200 may be exposed in accordance with the lower conductive pattern. Then, the first insulation interlayer 200 may be partially removed from the substrate 100 by an etching process using the mask pattern as an etching mask, to thereby form the first opening 205 through which the lower conductive pattern mat be exposed.

When the mask pattern is formed, dimensions of the openings to be formed may be predetermined and the mask pattern formed to correspond to the dimensions. After the patterns are formed, portions of the mask may be measured to determine the size of the openings to be formed. If the first openings 205 in the insulation layer 200 are to be rectangular or other polygonal shape, measurements may be made to determine the center point of the mask patterns to calculate the desired center points of the desired first openings 205. If the openings are to be circular or oval, measurements and dimensions may be scaled to determine the diameters of the mask patterns in order to determine the center points thereof and of corresponding first openings 205.

In an example embodiment, the etching process to remove the first insulation interlayer 200 may include a dry etching process using plasma. For example, source/drain regions of a DRAM memory device may be exposed through the first opening 205 and a string selection line region or a ground selection line region of a flash memory device may be exposed through the first opening 205. Then, a native oxide layer may be removed from a bottom of the first opening 205 by an addition process. The native oxide layer may be removed by the same etching process against the first insulation interlayer 200, as would be known to one of the ordinary skill in the art.

For example, the first opening 205 may include a contact hole to receive a conductive contact plug and a via-hole to receive a conductive via-plug to interconnect lower and upper metal wirings.

As illustrated in FIG. 2B, after the first openings 205 are formed, measurements may be made to verify whether the desired dimensions of the openings are accomplished, in order to test any variations between mask patterns and resultant openings. The measurements of the first openings 205 may then be used to determine a center point CP of the desired opening shape, and establish the center line C of the first opening 205.

Referring to FIGS. 1 and 2C, the interconnection 210 may be formed by filling up the opening 205 with first conductive materials such that the lower conductive pattern may be contacted with the interconnection 210. Since the center line C of the first opening 205 is positioned at the center point of the first opening 205, the interconnection 210 is also formed along the center line C to have sides equidistant from each of sides 201, 202 of the first opening 205.

In an example embodiment, the first conductive materials may be deposited onto the first insulation interlayer 200 to a sufficient thickness to fill up the first opening 205, thereby forming a first conductive layer (not illustrated) on the first insulation interlayer 200. Then, the first conductive layer may be partially removed from the first insulation interlayer 200 until a top surface of the first insulation interlayer 200 may be exposed. Thus, the first conductive layer may remain inside of the first opening 205, thereby forming the interconnection 210 in the first opening 205.

For example, the first conductive materials may include polysilicon, low electrical-resistive materials and combinations thereof. Examples of the low electrical-resistive materials may include tungsten (W), copper (Cu), aluminum (Al), tantalum (Ta), titanium (Ti) and combinations thereof. In the present example embodiment, the first conductive layer may be formed on the first insulation interlayer 200 by a metal plasma process using ionized metals and an atomic layer deposition (ALD) process to thereby reduce electrical resistance of the interconnection 210.

The first conducive layer needs to have a small thickness as much as possible so as to reduce the electrical resistance and the ALD process may be used to reduce the electrical resistance of the interconnection 210 in the present example embodiment. Thus, any other deposition processes may be used in place of the ALD process on condition that the deposition may be merely useful to reduce the electrical resistance of the interconnection 210. For example, a pulsed layer nucleation (PNL) deposition process and a cyclic CVD process may be used in place of or in conjunction with the ALD process of forming the interconnection 210.

In an example embodiment, a barrier layer (not shown) may be further formed on a sidewall and bottom of the first opening 205 and on a top surface of the first insulation interlayer 200 prior to the formation of the first conductive layer. The barrier layer may include a metal layer, a metal nitride layer and a double-layered structure having the metal nitride layer and the metal nitride layer. The first opening 205 may include a contact hole in which a conductive contact plug may be formed and a via-hole in which a via plug to electrically connect metal wirings may be formed.

In forming the interconnection 210 as illustrated in FIG. 2C, the first conducive layer may be partially removed from the first insulation interlayer 200 by a planarization process such as a CMP process and thus the first conductive layer may remain only in the first opening in such a manner that an upper surface of the interconnection 210 may be coplanar with the top surface of the first insulation interlayer 200.

Referring to FIGS. 1 and 2D, the first insulation interlayer 200 may be partially removed from the substrate 100 and thus the top surface S1 of the interconnection 210 may be higher than the upper surface S2 of the first insulation interlayer 200. That is, the interconnection 210 may be protruded from the upper surface of the first insulation interlayer 200.

A mask pattern (not illustrated) may be formed on the interconnection 210 and an upper portion of the first insulation interlayer 200 may be etched off from the substrate 100 by using the mask pattern as an etching mask. In other processes of the present general inventive concept, the first insulation interlayer 200 may be etched off from the substrate 100 without any etch of the interconnection 210 due to the difference of etch rate of the interconnection 210 and the first insulation interlayer 200.

Particularly, when the interconnection 210 may include a low resistive metal and the first insulation interlayer 200 may include an oxide, the first insulation interlayer 200 may be partially removed from the substrate 100 by a plasma etch process not using any etching mask while no portion of the interconnection 210 may be substantially etched off from the substrate 100. For example, chlorine (Cl2) gases or tetrafluoromethane (CF4) gases may be used as a source gases for the plasma-etch process.

Therefore, the interconnection 210 may be protruded from the upper surface of the first insulation interlayer 200 to a protrusion height h and the top surface S1 of the interconnection 210 may be higher than the top surface S2 of the first insulation interlayer 200. The protrusion height h of the interconnection 210 may be pre-determined as a terminal point of the etching process and may provide a stepped portion between the interconnection 210 and the second insulation interlayer 500 which may be formed in a subsequent process described below. Thus, the protrusion height h of the interconnection 210 may be determined in accordance with a size of the stepped portion between the interconnection 210 and the second insulation interlayer 500.

Referring to FIGS. 1 and 2E, the lower insulation layer 300 and the upper insulation layer 400 may be sequentially formed on the second insulation interlayer 200 having the interconnection 210, thereby forming the second insulation interlayer 500 on the first insulation interlayer 200.

Since the interconnection 210 may be protruded from the top surface S2 of the first insulation interlayer 200, the lower and the upper insulation layers 300 and 400 may be also protrude from the first insulation interlayer 200 in accordance with a surface profile of the first insulation interlayer 200 and the interconnection 210. Therefore, the lower and the upper insulation layers 300 and 400 may include first and second protrusion portions 300a and 400a to correspond to the protruded upper portion of the interconnection 210. Since the first and second protrusion portions 300a and 400a correspond to the protruded top surface S1 of the interconnection 210, the central axes of the portions 300a and 400a also correspond to the central axis C of the interconnection 210. The thickness or height of the first and the second protrusion portions 300a and 400a may be varied according to the protrusion height h of the interconnection 210 and step coverage of the lower and the upper insulation layers 300 and 400. Therefore, the terminal point of the etching process to remove the upper portion of the first insulation interlayer 200 and the material compositions of the lower and the higher insulation layers 300 and 400 may be determined in a view of the proper protrusion height h and the protrusion height h may be determined in a view of the size of the first and the second protrusion portions 300a and 400a.

Since the first and the second protrusion portions 300a and 400a may be formed on the first insulation interlayer 200 without any shape limitations in accordance with the upper portion of the interconnection 210, the first and the second protrusion portions 300a and 400a may have the same central axis C as the interconnection 210 formed within the first opening 205. That is, the interconnection 210 and the first and the second protrusion portions 300a and 400a may commonly share the same central axis C with one another.

In an example embodiment, the upper insulation layer 400 may include materials having etching resistivity higher than that of the lower insulation layer 300, thus the lower insulation layer 300 may be etched off more easily than the upper insulation layer 400 in the same etching process. For example, the etching rate of the lower insulation layer 300 may be from about 3 times to about 10 times the etching rate of the upper insulation layer 400 in the same etching process. In the present example embodiment, the upper insulation layer 400 may include silicon oxide and the lower insulation layer 300 may include silicon nitride so as to maintain the above-mentioned etching rate difference. In other processes, the upper insulation layer 400 may be include the same material as the first insulation interlayer 200 when the latter does not include silicon oxide.

Referring to FIGS. 1 and 2F, the upper insulation layer 400 may be partially removed from the lower insulation layer 300 in such a manner that upper surfaces of the lower and the upper insulation layers 300 and 400 may be coplanar with each other.

In an example embodiment, a planarization process such as a CMP process and an etch-back process may be performed on the upper insulation layer 400 until the upper surface of the lower insulation layer 300 may be exposed, and thus the upper insulation layer 400 may be partially removed from the second insulation interlayer 500 in such a manner that the second protrusion portion 400a may be removed and the first protrusion portion 300a may be exposed. Thus, the upper surfaces of the lower and the upper insulation layers 300 and 400 may be coplanar with each other and thus an upper surface of the second insulation interlayer 500 may be planarized by the planarization process.

Referring to FIGS. 1 and 2G, the lower insulation layer 300 may be partially removed from the second insulation interlayer 500 to thereby form the second opening 505 through which the upper portion of the interconnection 210 may be exposed.

In an example embodiment, an anisotropic etching process may be performed on the planarized upper surface of the second insulation interlayer 500 and thus the lower insulation layer 300 may be removed downwardly from a surface of the first protrusion portion 300a over the interconnection 210, thereby forming the second opening 505 through which the upper portion of the interconnection 210 may be exposed.

In the present example embodiment, the upper insulation layer 400 may have a sufficient thickness to remain on the lower insulation layer 300 despite the anisotropic etching process of forming the second opening 505. Thus, the upper insulation layer 400 may still remain on the lower insulation layer 300 when the anisotropic etching process of forming the second opening 505 may be finished. Therefore, the dimensions of the second opening 505 may be defined by the dimensions of both of the lower and the upper insulation layers 300 and 400. The thickness of the upper conductive pattern 510, which may be formed in the second opening 505 in a subsequent process, may be determined by a depth of the second opening 505. In a modified example embodiment, the second opening 505 may be defined merely by the lower insulation layer 300 in view of process conditions and device requirements, as would be known to one of the ordinary skill in the art. That is, the thickness of the upper insulation layer 400 may be varied in accordance with the process conditions of the etching process of forming the second opening 505.

For example, the anisotropic etching process may include a wet etching process using an aqueous HF solution and a plasma etching process, to thereby minimize damage to the exposed interconnection 210 caused by the anisotropic etching process. Particularly, the first insulation interlayer 200 may be function as an etch stop layer for the anisotropic etching process, thereby preventing the second opening 505 from horizontally enlarging along the first insulation interlayer 200. When the upper insulation layer 400 and the first insulation interlayer 200 may include the same material of an oxide, the lower insulation layer 300 defining the second opening 505 may be etched off much more rapidly than the first insulation interlayer 200 adjacent to the interconnection 210 during the above anisotropic etching process, and thus the second opening 505 may be rapidly enlarged horizontally along the second insulation interlayer 200. For that reason, the anisotropic etching process may be terminated at a time when the first insulation interlayer 200 may be exposed and the upper portion of the interconnection 210 may be partially protruded from the first insulation interlayer 200 to a maximal length of the protrusion height h.

Since the first protrusion portion 300a illustrated in FIG. 2E having the same central axis line of the interconnection 210 may be removed by the anisotropic etching process, the second opening 505 that is created by the removal of the first protrusion portion 300a will have the same edge as an etch stop portion 400b of the upper insulation layer 400, and have the same dimensions including the same width of the first protrusion portion 300a. Thus, a center of the second opening 505 may also be positioned on the central axis line. Thus, the second opening 505 formed as a result of the removal of a portion of the lower insulation layer 300 may be automatically centrally self-aligned with the interconnection 210. Thus, the central axis C that defined the first protrusion 300a becomes the same central axis C of the second opening 505.

Thus, after the central axis C is first determined upon formation of the first opening 205, all the subsequent conductive layers and openings that are formed above the first opening 205 are aligned and can be self-aligned with the first opening 205 to have the same central axis C as the first opening 205.

Referring to FIGS. 1 and 2H, second conductive materials may be deposited onto the second insulation interlayer 500 having the second opening 505, thereby forming a second conducive layer (not illustrated) on the second insulation interlayer 500 to a sufficient thickness to fill up the second opening 505. Then, the second conductive layer may be planarized by a planarization process until the upper surface of the upper insulation layer 400 may be exposed and thus the second conducive layer may remain only in the second opening 505, to thereby form the upper conducive pattern 510 in the second opening 505.

The second conductive materials may include polysilicon, aluminum (Al), copper (Cu), tungsten (W), titanium (Ti), tantalum (Ta) and combinations thereof. In the present example embodiment, the second conductive layer may include the same material as the interconnection 210.

Accordingly, since the second opening 505 may be centrally self-aligned with the interconnection 210 and the upper conductive pattern 510 may be formed in the second opening 505, the upper conductive pattern 510 may be centrally self-aligned with the underlying interconnection 210.

According to the present example method of manufacturing a semiconductor device, the upper conductive pattern 510 may be centrally self-aligned with the underlying interconnection 210, to thereby prevent the bridge defect caused by mis-alignment between the interconnection and the upper conductive pattern.

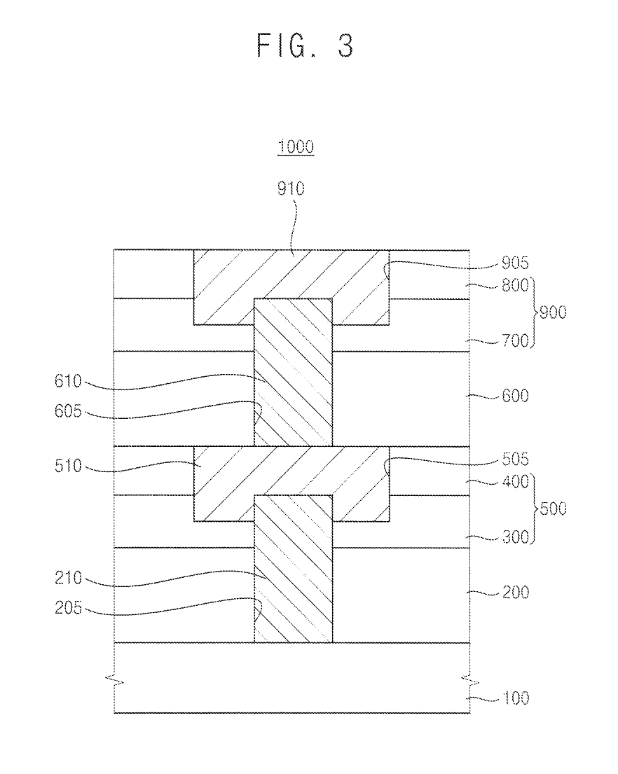

FIG. 3 is a cross-sectional view illustrating a multi-level semiconductor device including a central-aligned interconnection scheme in accordance with an example embodiment of the present general inventive concept.

The semiconductor device 1000 may include the insulation layers 200, 300 and 400 as previously described, centrally aligned with the first opening 205 as described herein. Additionally, the semiconductor device 1000 may include additional interconnections and conductive patterns to form multiple layer connection patterns to connect components of multiple stacked integrated circuit layers. Though illustrated as a two-layer structure, the interconnection scheme including self-alignment and centrally aligned openings and interconnection may include a plurality of levels of interconnect exceeding the two illustrated levels.

As illustrated in FIG. 3, a second insulation interlayer 600 may be formed over the second insulation layer 500 and the upper conductive pattern 510. Similar processes as described and illustrated in FIGS. 2A-2H above may be used to form masking layers, openings, interconnection layers and conductive patterns to form the second insulation interlayer 600 and a third opening 605 along the central axis C. The exemplary embodiment may also include an interconnection 610, a third insulation layer 900 including a second lower insulation layer 700 and a second upper insulation layer 800, a third opening 905 and a second upper conductive pattern 910. As above, all of the conductive layers and openings may be self-aligned with the first opening 205 and the interconnection 210. In this way, more elaborate and accurate interconnection schemes may be manufactured which may allow smaller contact areas to be more accurately aligned to connect electrical components such as interconnections and conductive patterns through thicker insulation interlayers and multiple integrated circuit layers.

According to the example embodiments of the present general inventive concept, the second opening through which the interconnection may be exposed may be centrally self-aligned with the interconnection not by a photolithography process using a mask pattern but by etching rate difference between the first insulation interlayer and the second insulation interlayer, and thus the upper conductive pattern may be centrally self-aligned with the interconnection automatically. Thus, various process defects caused by mis-alignment between the interconnection and the upper conductive pattern may be sufficiently prevented. Particularly, the mis-alignment between the contact plug and the metal wiring in a multi-layered wiring structure may be significantly minimized despite reduction of the critical dimension of a semiconductor device, to thereby sufficiently reduce the bridge defect in the semiconductor device.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present general inventive concept. Accordingly, all such modifications are intended to be included within the scope of the present general inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

Although a few embodiments of the present general inventive concept have been illustrated and described, it would be appreciated by those skilled in the art that changes may be made in these embodiments without departing from the principles and spirit of the present general inventive concept, the scope of which is defined in the claims and their equivalents.

1-4. (canceled)

5. A method of forming a semiconductor device, comprising:
preparing a substrate having at least a lower conductive pattern;
forming a first insulation interlayer on the substrate in such a manner that the lower conductive pattern is covered with the first insulation interlayer and is electrically insulated by the first insulation interlayer and the first insulation interlayer has a first opening through which the lower conductive pattern is exposed;
forming an interconnection in the first opening in such a manner that the interconnection is contacted with the lower conductive pattern and is protruded from the first insulation interlayer, so that an upper surface of the interconnection is higher than an upper surface of the first insulation interlayer;
forming a second insulation interlayer on the first insulation interlayer in such a manner that the second insulation interlayer has a second opening through which the interconnection is exposed and the second opening is centrally aligned with the interconnection; and
forming at least an upper conductive pattern in the second opening such that the upper conductive pattern is contacted with the interconnection.

6. The method of claim 5, wherein forming the second insulation interlayer includes:
forming a lower insulation layer on the first insulation interlayer from which the interconnection is protruded to a sufficient thickness to cover the protruded interconnection, so that the lower insulation layer includes a first protrusion portion to correspond to the protruded portion of the interconnection;
forming an upper insulation layer on the lower insulation layer along a surface profile of the lower insulation layer in such a manner that the upper insulation layer has an etching rate smaller than that of the lower insulation layer, so that the upper insulation layer includes a second protrusion portion to correspond to the first protrusion portion of the lower insulation layer;
partially removing the upper insulation layer until an upper surface of the first protrusion of the lower insulation layer is exposed, so that an upper surface of the upper insulation layer is coplanar with the upper surface of the first protrusion of the lower insulation layer; and
partially removing the first protrusion portion of the lower insulation layer, to thereby forming the second opening through which the protruded portion of the interconnection is exposed.

7. The method of claim 6, wherein partially removing the upper insulation layer is performed by one of chemical mechanical polishing (CMP) process and an etch-back process against the upper insulation layer.

8. The method of claim 6, wherein the etching rate of the lower insulation layer is from about 3 times to about 10 times the etching rate of the upper insulation layer.

9. The method of claim 6, wherein removing the first protrusion portion of the lower insulation layer is performed by one of a wet etching process using an aqueous HF solution as an etchant and a plasma dry etching process.

10. The method of claim 6, wherein the interconnection and the upper conductive pattern includes one of polysilicon, a low electrical resistive metal and combinations thereof.

11. The method of claim 10, wherein the low electrical resistive metal includes any one material selected from the group consisting of tungsten (W), titanium (Ti), tantalum (Ta) and combinations thereof.

12. A method of forming a semiconductor device, comprising:
forming a substrate having a lower conductive pattern formed thereon;
forming a first insulation interlayer over the substrate and the conductive pattern;
masking the first insulation interlayer to form an opening of a predetermined size;
forming the opening and determining a central axis of the opening equidistant from the sides of the first insulation layer that define the opening;
forming a conductive interconnect in the first opening;
forming a plurality of insulation layers above the conductive interconnect; and
self-aligning a second opening over the first opening such that a center of the second opening is centrally aligned with the central axis of the first opening.

13. The method of claim 12, further comprising:
forming a lower insulation layer to protrude above the conductive interconnect, the lower insulation layer having a first etch selectivity;
forming an upper insulation layer above the lower insulation layer, the upper insulation layer having a second etch selectivity higher than the first etch selectivity;
removing a top portion of the upper insulation layer to expose an upper surface of the lower insulation layer; and
etching the lower insulation layer to a width edge barrier of the upper insulation film that acts as an etch stop to define the sides of the second opening.

14. The method of claim 13, further comprising anistropically etching a surface of the lower insulation layer to downwardly remove the lower insulation layer to expose a top portion of the conductive interconnect within the second opening.

15. The method of claim 14, wherein the first insulation interlayer acts as an etch stop layer for the anisotropic etching process, thereby preventing the second opening from horizontally enlarging along the first insulation interlayer.

16. The method of claim 13, wherein the lower and upper insulation layers include protrusion portions that have the same central axis as the conductive interconnect formed within the first opening.

17. The method of claim 12, further comprising:
depositing a conductive pattern in the second opening to be centrally aligned with the first opening.

18. The method of claim 12, wherein the second opening is defined by dimensions of the plurality of insulating layers.
